(19) United States
(12) Patent Application Publication
(10) Pub. No.: US 2025/0009038 A1
(43) Pub. Date: Jan. 9, 2025

(54) AEROSOL-GENERATING DEVICE AND OPERATION METHOD THEREOF

(71) Applicant: KT&G CORPORATION, Daejeon (KR)

(72) Inventors: Byungsung CHO, Gwangmyung-si Gyeonggi-do (KR); Jaemin LEE, Siheung-si, Gyeonggi-do (KR); Sangkyu PARK, Seoul (KR); Jongsub LEE, Sungnam-si Gyeonggi-do (KR)

(73) Assignee: KT&G CORPORATION, Daejeon (KR)

(21) Appl. No.: 18/697,934

(22) PCT Filed: Oct. 19, 2022
(86) PCT No.: PCT/KR2022/015922

§ 371 Date: Apr. 2, 2024

(30) Foreign Application Priority Data
Oct. 19, 2021 (KR) 10-2021-0139783
Jan. 19, 2022 (KR) 10-2022-0007995

(51) Int. Cl. A24F 40/51; A24F 40/57; H03H 17/02

(52) U.S. Cl. CPC A24F 40/51; A24F 40/57; H03H 17/02

(57) ABSTRACT

An aerosol-generating device and an operation method thereof are disclosed. The aerosol-generating device of the disclosure includes a heater configured to heat an aerosol-generating substance, a puff sensor configured to detect a puff, and a controller configured to process a signal from the puff sensor. The controller determines a first frequency corresponding to a first puff time period and a second frequency corresponding to a second puff time period, which is longer than the first puff time period, filters the signal from the puff sensor based on the first frequency and the second frequency, and adjusts the power supplied to the heater based on the result of filtering. The first frequency is a frequency lower than the second frequency.

### TECHNICAL FIELD

The present disclosure relates to an aerosol-generating device and an operation method thereof.

### BACKGROUND ART

An aerosol-generating device is a device that extracts certain components from a medium or a substance by forming an aerosol. The medium may contain a multicomponent substance. The substance contained in the medium may be a multicomponent flavoring substance. For example, the substance contained in the medium may include a nicotine component, an herbal component, and/or a coffee component. Recently, various research on aerosol-generating devices has been conducted.

### DISCLOSURE

### Technical Problem

It is an object of the present disclosure to solve the above and other problems.

It is another object of the present disclosure to provide an aerosol-generating device and an operation method thereof capable of accurately filtering a signal from a puff sensor based on digital filtering using a plurality of frequencies.

It is still another object of the present disclosure to provide an aerosol-generating device and an operation method thereof capable of improving the accuracy of filtering of a signal from a puff sensor based on a user's puff time period.

### Technical Solution

An aerosol-generating device according to an aspect of the present disclosure for accomplishing the above and other objects may include a heater configured to heat an aerosol-generating substance, a puff sensor configured to detect a puff, and a controller configured to process a signal from the puff sensor. The controller may determine a first frequency corresponding to a first puff time period and a second frequency corresponding to a second puff time period, which is longer than the first puff time period, may filter the signal from the puff sensor based on the first frequency and the second frequency, and may adjust the power supplied to the heater based on the result of filtering. The first frequency may be a frequency lower than the second frequency.

An operation method of an aerosol-generating device according to an aspect of the present disclosure for accomplishing the above and other objects may include determining a first frequency corresponding to a first puff time period and a second frequency corresponding to a second puff time period, which is longer than the first puff time period, filtering a signal from a puff sensor, configured to detect a puff, based on the first frequency and the second frequency, and adjusting the power supplied to a heater, configured to heat an aerosol-generating substance, based on the result of the filtering. The first frequency may be a frequency lower than the second frequency.

### ADVANTAGEOUS EFFECTS

According to at least one of embodiments of the present disclosure, a signal from a puff sensor may be accurately filtered based on digital filtering using a plurality of frequencies.

According to at least one of embodiments of the present disclosure, the accuracy of filtering of a signal from a puff sensor may be improved based on a user's puff time period.

Additional applications of the present disclosure will become apparent from the following detailed description. However, because various changes and modifications will be clearly understood by those skilled in the art within the spirit and scope of the present disclosure, it should be understood that the detailed description and specific embodiments, such as preferred embodiments of the present disclosure, are merely given by way of example.

### DESCRIPTION OF DRAWINGS

The above and other objects, features and other advantages of the present disclosure will be more clearly understood from the following detailed description taken in conjunction with the accompanying drawings, in which:

FIG. 1 is a block diagram of an aerosol-generating device according to an embodiment of the present disclosure;

FIGS. 2 to 4 are views for explaining an aerosol-generating device according to embodiments of the present disclosure;

FIGS. 5 to 7 are views for explaining a stick according to embodiments of the present disclosure;

FIG. 8 is a view for explaining elements of the aerosol-generating device according to embodiments of the present disclosure;

FIG. 9 is a flowchart showing an operation method of the aerosol-generating device according to an embodiment of the present disclosure; FIGS. 10 to 12 are views for explaining the operation of the aerosol-generating device; and

FIG. 13 is a flowchart showing an operation method of the aerosol-generating device according to another embodiment of the present disclosure.

### BEST MODE

Hereinafter, the embodiments disclosed in the present specification will be described in detail with reference to the accompanying drawings. The same or similar elements are denoted by the same reference numerals even though they are depicted in different drawings, and redundant descriptions thereof will be omitted.

In the following description, with respect to constituent elements used in the following description, the suffixes “module” and “unit” are used only in consideration of facilitation of description. The “module” and “unit” are do not have mutually distinguished meanings or functions.

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and sprit of the present disclosure.

It will be understood that the terms “first”, “second”, etc., may be used herein to describe various components. However, these components should not be limited by these terms. These terms are only used to distinguish one component from another component.

It will be understood that when a component is referred to as being “connected to” or “coupled to” another component, it may be directly connected to or coupled to another component. However, it will be understood that intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

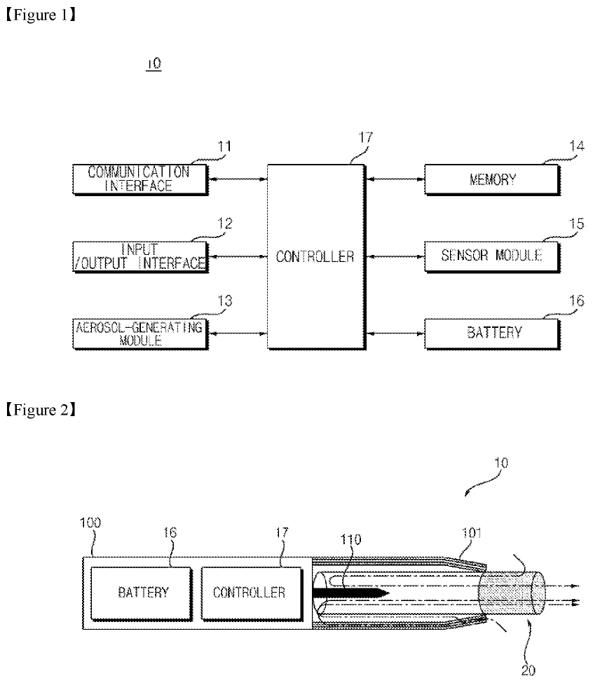

FIG. 1 is a block diagram of an aerosol-generating device according to an embodiment of the present disclosure.

Referring to FIG. 1, an aerosol-generating device 10 may include a communication interface 11, an input/output interface 12, an aerosol-generating module 13, a memory 14, a sensor module 15, a battery 16, and/or a controller 17.

In one embodiment, the aerosol-generating device 10 may be composed only of a main body. In this case, components included in the aerosol-generating device 10 may be located in the main body. In another embodiment, the aerosol-generating device 10 may be composed of a cartridge, which contains an aerosol-generating substance, and a main body. In this case, the components included in the aerosol-generating device 10 may be located in at least one of the main body or the cartridge.

The communication interface 11 may include at least one communication module for communication with an external device and/or a network. For example, the communication interface 11 may include a communication module for wired communication, such as a Universal Serial Bus (USB). For example, the communication interface 11 may include a communication module for wireless communication, such as Wireless Fidelity (Wi-Fi), Bluetooth, Bluetooth Low Energy (BLE), ZigBee, or nearfield communication (NFC).

The input/output interface 12 may include an input device (not shown) for receiving a command from a user and/or an output device (not shown) for outputting information to the user. For example, the input device may include a touch panel, a physical button, a microphone, or the like. For example, the output device may include a display device for outputting visual information, such as a display or a light-emitting diode (LED), an audio device for outputting auditory information, such as a speaker or a buzzer, a motor for outputting tactile information such as haptic effect, or the like.

The input/output interface 12 may transmit data corresponding to a command input by the user through the input device to another component (or other components) of the aerosol-generating device 100. The input/output interface 12 may output information corresponding to data received from another component (or other components) of the aerosol-generating device 10 through the output device.

The aerosol-generating module 13 may generate an aerosol from an aerosol-generating substance. Here, the aerosol-generating substance may be a substance in a liquid state, a solid state, or a gel state, which is capable of generating an aerosol, or a combination of two or more aerosol-generating substances.

According to an embodiment, the liquid aerosol-generating substance may be a liquid including a tobacco-containing material having a volatile tobacco flavor component. According to another embodiment, the liquid aerosol-generating substance may be a liquid including a non-tobacco material. For example, the liquid aerosol-generating substance may include water, solvents, nicotine, plant extracts, flavorings, flavoring agents, vitamin mixtures, etc.

The solid aerosol-generating substance may include a solid material based on a tobacco raw material such as a reconstituted tobacco sheet, shredded tobacco, or granulated tobacco. In addition, the solid aerosol-generating substance may include a solid material having a taste control agent and a flavoring material. For example, the taste control agent may include calcium carbonate, sodium bicarbonate, calcium oxide, etc. For example, the flavoring material may include a natural material such as herbal granules, or may include a material such as silica, zeolite, or dextrin, which includes an aroma ingredient.

In addition, the aerosol-generating substance may further include an aerosol-forming agent such as glycerin or propylene glycol.

The aerosol-generating module 13 may include at least one heater (not shown).

The aerosol-generating module 13 may include an electro-resistive heater. For example, the electro-resistive heater may include at least one electrically conductive track. The electro-resistive heater may be heated as current flows through the electrically conductive track. At this time, the aerosol-generating substance may be heated by the heated electro-resistive heater.

The electrically conductive track may include an electro-resistive material. In one example, the electrically conductive track may be formed of a metal material. In another example, the electrically conductive track may be formed of a ceramic material, carbon, a metal alloy, or a composite of a ceramic material and metal.

The electro-resistive heater may include an electrically conductive track that is formed in any of various shapes. For example, the electrically conductive track may be formed in any one of a tubular shape, a plate shape, a needle shape, a rod shape, and a coil shape.

The aerosol-generating module 13 may include a heater that uses an induction-heating method. For example, the induction heater may include an electrically conductive coil. The induction heater may generate an alternating magnetic field, which periodically changes in direction, by adjusting the current flowing through the electrically conductive coil. At this time, when the alternating magnetic field is applied to a magnetic body, energy loss may occur in the magnetic body due to eddy current loss and hysteresis loss. In addition, the lost energy may be released as thermal energy. Accordingly, the aerosol-generating substance located adjacent to the magnetic body may be heated. Here, an object that generates heat due to the magnetic field may be referred to as a susceptor.

Meanwhile, the aerosol-generating module 13 may generate ultrasonic vibrations to thereby generate an aerosol from the aerosol-generating substance.

The aerosol-generating device 10 may be referred to as a cartomizer, an atomizer, or a vaporizer.

The memory 14 may store programs for processing and controlling each signal in the controller 17. The memory 14 may store processed data and data to be processed.

For example, the memory 14 may store applications designed for the purpose of performing various tasks that can be processed by the controller 17. The memory 14 may selectively provide some of the stored applications in response to the request from the controller 17.

For example, the memory 14 may store data on the operation time of the aerosol-generating device 100, the maximum number of puffs, the current number of puffs, the number of uses of battery 16, at least one temperature profile, the user's inhalation pattern, and data about charging/discharging. Here, “puff” means inhalation by the user. “inhalation” means the user's act of taking air or other substances into the user's oral cavity, nasal cavity, or lungs through the user's mouth or nose.

The memory 14 may include at least one of volatile memory (e.g. dynamic random access memory (DRAM), static random access memory (SRAM), or synchronous dynamic random access memory (SDRAM)), nonvolatile memory (e.g. flash memory), a hard disk drive (HDD), or a solid-state drive (SSD).

The sensor module 15 may include at least one sensor.

For example, the sensor module 15 may include a sensor for sensing a puff (hereinafter referred to as a “puff sensor”). In this case, the puff sensor may be implemented as a proximity sensor such as an IR sensor, a pressure sensor, a gyro sensor, an acceleration sensor, a magnetic field sensor, or the like.

For example, the sensor module 15 may include a sensor for sensing a puff (hereinafter referred to as a “puff sensor”). In this case, the puff sensor may be implemented by a pressure sensor, a gyro sensor, an acceleration sensor, a magnetic field sensor, or the like.

For example, the sensor module 15 may include a sensor for sensing the temperature of the heater included in the aerosol-generating module 13 and the temperature of the aerosol-generating substance (hereinafter referred to as a “temperature sensor”). In this case, the heater included in the aerosol-generating module 13 may also serve as the temperature sensor. For example, the electro-resistive material of the heater may be a material having a predetermined temperature coefficient of resistance. The sensor module 15 may measure the resistance of the heater, which varies according to the temperature, to thereby sense the temperature of the heater.

For example, in the case in which the main body of the aerosol-generating device 10 is formed to allow a stick to be inserted thereinto, the sensor module 15 may include a sensor for sensing insertion of the stick (hereinafter referred to as a “stick detection sensor”).

For example, in the case in which the aerosol-generating device 10 includes a cartridge, the sensor module 15 may include a sensor for sensing mounting/demounting of the cartridge and the position of the cartridge (hereinafter referred to as a “cartridge detection sensor”).

In this case, the stick detection sensor and/or the cartridge detection sensor may be implemented as an inductance-based sensor, a capacitive sensor, a resistance sensor, or a Hall sensor (or Hall IC) using a Hall effect.

For example, the sensor module 15 may include a voltage sensor for sensing a voltage applied to a component (e.g. the battery 16) provided in the aerosol-generating device 10 and/or a current sensor for sensing a current.

The battery 16 may supply electric power used for the operation of the aerosol-generating device 10 under the control of the controller 17. The battery 16 may supply electric power to other components provided in the aerosol-generating device 100. For example, the battery 16 may supply electric power to the communication module included in the communication interface 11, the output device included in the input/output interface 12, and the heater included in the aerosol-generating module 13.

The battery 16 may be a rechargeable battery or a disposable battery. For example, the battery 16 may be a lithium-ion (Li-ion) battery or a lithium polymer (Li-polymer) battery. However, the present disclosure is not limited thereto. For example, when the battery 16 is rechargeable, the charging rate (C-rate) of the battery 16 may be 10 C, and the discharging rate (C-rate) thereof may be 10 C to 20 C. However, the present disclosure is not limited thereto. Also, for stable use, the battery 16 may be manufactured such that 80% or more of the total capacity may be ensured even when charging/discharging is performed 2000 times.

The aerosol-generating device 10 may further include a battery protection circuit module (PCM) (not shown), which is a circuit for protecting the battery 16. The battery protection circuit module (PCM) may be disposed adjacent to the upper surface of the battery 16. For example, in order to prevent overcharging and overdischarging of the battery 16, the battery protection circuit module (PCM) may cut off the electrical path to the battery 16 when a short circuit occurs in a circuit connected to the battery 16, when an overvoltage is applied to the battery 16, or when an overcurrent flows through the battery 16.

The aerosol-generating device 10 may further include a charging terminal to which electric power supplied from the outside is input. For example, the charging terminal may be formed at one side of the main body of the aerosol-generating device 100. The aerosol-generating device 10 may charge the battery 16 using electric power supplied through the charging terminal. In this case, the charging terminal may be configured as a wired terminal for USB communication, a pogo pin, or the like.

The aerosol-generating device 10 may further include a power terminal (not shown) to which electric power supplied from the outside is input. For example, a power line may be connected to the power terminal, which is disposed at one side of the main body of the aerosol-generating device 100. The aerosol-generating device 10 may use the electric power supplied through the power line connected to the power terminal to charge the battery 16. In this case, the power terminal may be a wired terminal for USB communication.

The aerosol-generating device 10 may wirelessly receive electric power supplied from the outside through the communication interface 11. For example, the aerosol-generating device 10 may wirelessly receive electric power using an antenna included in the communication module for wireless communication. The aerosol-generating device 10 may charge the battery 16 using the wirelessly supplied electric power.

The controller 17 may control the overall operation of the aerosol-generating device 100. The controller 17 may be connected to each of the components provided in the aerosol-generating device 100. The controller 17 may transmit and/or receive a signal to and/or from each of the components, thereby controlling the overall operation of each of the components.

The controller 17 may include at least one processor. The controller 17 may control the overall operation of the aerosol-generating device 10 using the processor included therein. Here, the processor may be a general processor such as a central processing unit (CPU). Of course, the processor may be a dedicated device such as an application-specific integrated circuit (ASIC), or may be any of other hardware-based processors.

The controller 17 may perform any one of a plurality of functions of the aerosol-generating device 100. For example, the controller 17 may perform any one of a plurality of functions of the aerosol-generating device 10 (e.g. a preheating function, a heating function, a charging function, and a cleaning function) according to the state of each of the components provided in the aerosol-generating device 10 and the user's command received through the input/output interface 12.

The controller 17 may control the operation of each of the components provided in the aerosol-generating device 10 based on data stored in the memory 14. For example, the controller 17 may control the supply of a predetermined amount of electric power from the battery 16 to the aerosol-generating module 13 for a predetermined time based on the data on the temperature profile, the user's inhalation pattern, which is stored in the memory 14.

The controller 17 may determine the occurrence or non-occurrence of a puff using the puff sensor included in the sensor module 15. For example, the controller 17 may check a temperature change, a flow change, a pressure change, and a voltage change in the aerosol-generating device 10 based on the values sensed by the puff sensor. The controller 17 may determine the occurrence or non-occurrence of a puff based on the value sensed by the puff sensor.

The controller 17 may control the operation of each of the components provided in the aerosol-generating device 10 according to the occurrence or non-occurrence of a puff and/or the number of puffs. For example, the controller 17 may perform control such that the temperature of the heater is changed or maintained based on the temperature profile stored in the memory 14.

The controller 17 may perform control such that the supply of electric power to the heater is interrupted according to a predetermined condition. For example, the controller 17 may perform control such that the supply of electric power to the heater is interrupted when the stick is removed, when the cartridge is demounted, when the number of puffs reaches the predetermined maximum number of puffs, when a puff is not sensed during a predetermined period of time or longer, or when the remaining capacity of the battery 16 is less than a predetermined value.

The controller 17 may calculate the remaining capacity with respect to the full charge capacity of the battery 16. For example, the controller 17 may calculate the remaining capacity of the battery 16 based on the values sensed by the voltage sensor and/or the current sensor included in the sensor module 15.

The controller 17 may perform control such that electric power is supplied to the heater using at least one of a pulse width modulation (PWM) method or a proportional-integral-differential (PID) method.

For example, the controller 17 may perform control such that a current pulse having a predetermined frequency and a predetermined duty ratio is supplied to the heater using the PWM method. In this case, the controller 17 may control the amount of electric power supplied to the heater by adjusting the frequency and the duty ratio of the current pulse.

For example, the controller 17 may determine a target temperature to be controlled based on the temperature profile. In this case, the controller 17 may control the amount of electric power supplied to the heater using the PID method, which is a feedback control method using a difference value between the temperature of the heater and the target temperature, a value obtained by integrating the difference value with respect to time, and a value obtained by differentiating the difference value with respect to time.

Although the PWM method and the PID method are described as examples of methods of controlling the supply of electric power to the heater, the present disclosure is not limited thereto, and may employ any of various control methods, such as a proportional-integral (PI) method or a proportional-differential (PD) method.

Meanwhile, the controller 17 may perform control such that electric power is supplied to the heater according to a predetermined condition. For example, when a cleaning function for cleaning the space into which the stick is inserted is selected in response to a command input by the user through the input/output interface 12, the controller 17 may perform control such that a predetermined amount of electric power is supplied to the heater.

FIGS. 2 to 4 are views for explaining an aerosol-generating device according to embodiments of the present disclosure.

According to various embodiments of the present disclosure, the aerosol-generating device 10 may include a main body 100 and/or a cartridge 200.

Referring to FIG. 2, the aerosol-generating device 10 according to an embodiment may include a main body 100, which is formed such that a stick 20 can be inserted into the inner space formed by a housing 101.

The stick 20 may be similar to a general combustive cigarette. For example, the stick 20 may be divided into a first portion including an aerosol generating material and a second portion including a filter and the like. Alternatively, an aerosol generating material may be included in the second portion of the stick 20. For example, a flavoring substance made in the form of granules or capsules may be inserted into the second portion.

The entire first portion is inserted into the insertion space of the aerosol-generating device 10, and the second portion may be exposed to the outside. Alternatively, only a portion of the first portion may be inserted into the insertion space of the aerosol-generating device 10, or a portion of the first portion and the second portion may be inserted. In this case, the aerosol may be generated by passing external air through the first portion, and the generated aerosol may be delivered to the user's mouth through the second portion.

The main body 100 may be structured such that external air is introduced into the main body 100 in the state in which the stick 20 is inserted thereinto. In this case, the external air introduced into the main body 100 may flow into the mouth of the user via the stick 20.

The heater may be disposed in the main body 100 at a position corresponding to the position at which the stick 20 is inserted into the main body 100. Although it is illustrated in the drawings that the heater is an electrically conductive heater 110 including a needle-shaped electrically conductive track, the present disclosure is not limited thereto.

The heater may heat the interior and/or exterior of the stick 20 using the electric power supplied from the battery 16. An aerosol may be generated from the heated stick 20. At this time, the user may hold one end of the stick 20 in the mouth to inhale the aerosol containing a tobacco material.

Meanwhile, the controller 17 may perform control such that electric power is supplied to the heater in the state in which the stick 20 is not inserted into the main body according to a predetermined condition. For example, when a cleaning function for cleaning the space into which the stick 20 is inserted is selected in response to a command input by the user through the input/output interface 12, the controller 17 may perform control such that a predetermined amount of electric power is supplied to the heater.

The controller 17 may monitor the number of puffs based on the value sensed by the puff sensor from the point in time at which the stick 20 was inserted into the main body.

When the stick 20 is removed from the main body, the controller 17 may initialize the current number of puffs stored in the memory 14.

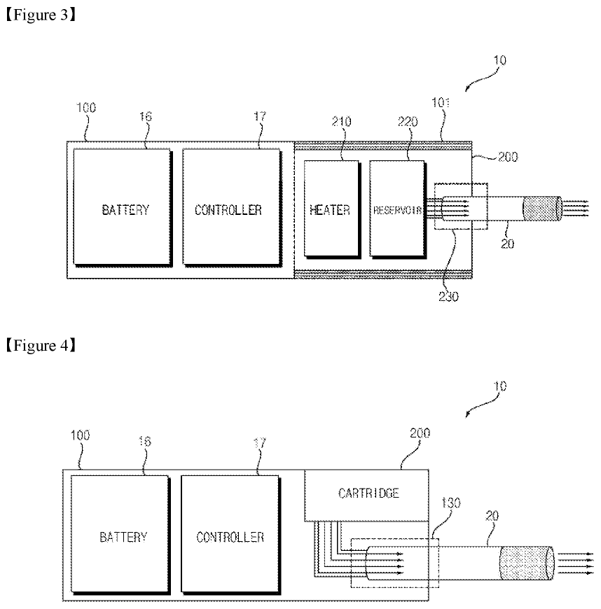

Referring to FIG. 3, the aerosol-generating device 10 according to an embodiment may include a main body 100 and a cartridge 200. The main body 100 may support the cartridge 200, and the cartridge 200 may contain an aerosol-generating substance.

According to one embodiment, the cartridge 200 may be configured so as to be detachably mounted to the main body 100. According to another embodiment, the cartridge 200 may be integrally configured with the main body 100. For example, the cartridge 200 may be mounted to the main body 100 in a manner such that at least a portion of the cartridge 200 is inserted into the insertion space formed by a housing 101 of the main body 100.

The main body 100 may be formed to have a structure in which external air can be introduced into the main body 100 in the state in which the cartridge 200 is inserted thereinto. Here, the external air introduced into the main body 100 may flow into the user's mouth via the cartridge 200.

The controller 17 may determine whether the cartridge 200 is in a mounted state or a detached state using a cartridge detection sensor included in the sensor module 15. For example, the cartridge detection sensor may transmit a pulse current through a first terminal connected with the cartridge 200. In this case, the controller 17 may determine whether the cartridge 200 is in a connected state, based on whether the pulse current is received through a second terminal.

The cartridge 200 may include a heater 210 configured to heat the aerosol-generating substance and/or a reservoir 220 configured to contain the aerosol-generating substance. For example, a liquid delivery element impregnated with (containing) the aerosol-generating substance may be disposed inside the reservoir 220. The electrically conductive track of the heater 210 may be formed in a structure that is wound around the liquid delivery element. In this case, when the liquid delivery element is heated by the heater 210, an aerosol may be generated. Here, the liquid delivery element may include a wick made of, for example, cotton fiber, ceramic fiber, glass fiber, or porous ceramic.

The cartridge 200 may include an insertion space 230 configured to allow the stick 20 to be inserted. For example, the cartridge 200 may include the insertion space formed by an inner wall extending in a circumferential direction along a direction in which the stick 20 is inserted. In this case, the insertion space may be formed by opening the inner side of the inner wall up and down. The stick 20 may be inserted into the insertion space formed by the inner wall.

The insertion space into which the stick 20 is inserted may be formed in a shape corresponding to the shape of a portion of the stick 20 inserted into the insertion space. For example, when the stick 20 is formed in a cylindrical shape, the insertion space may be formed in a cylindrical shape.

When the stick 20 is inserted into the insertion space, the outer surface of the stick 20 may be surrounded by the inner wall and contact the inner wall.

A portion of the stick 20 may be inserted into the insertion space, the remaining portion of the stick 20 may be exposed to the outside.

The user may inhale the aerosol while biting one end of the stick 20 with the mouth. The aerosol generated by the heater 210 may pass through the stick 20 and be delivered to the user's mouth. At this time, while the aerosol passes through the stick 20, the material contained in the stick 20 may be added to the aerosol. The material-infused aerosol may be inhaled into the user's oral cavity through the one end of the stick 20.

Referring to FIG. 4, the aerosol-generating device 10 according to an embodiment may include a main body 100 supporting the cartridge 200 and a cartridge 200 containing an aerosol-generating substance. The main body 100 may be formed so as to allow the stick 20 to be inserted into an insertion space 130 therein.

The aerosol-generating device 10 may include a first heater for heating the aerosol-generating substance stored in the cartridge 200. For example, when the user holds one end of the stick 20 in the mouth to inhale the aerosol, the aerosol generated by the first heater may pass through the stick 20. At this time, while the aerosol passes through the stick 20, a flavor may be added to the aerosol. The aerosol containing the flavor may be drawn into the user's oral cavity through one end of the stick 20.

Alternatively, according to another embodiment, the aerosol-generating device 10 may include a first heater for heating the aerosol-generating substance stored in the cartridge 200 and a second heater for heating the stick 20 inserted into the main body 100. For example, the aerosol-generating device 10 may generate an aerosol by heating the aerosol-generating substance stored in the cartridge 200 and the stick 20 using the first heater and the second heater, respectively.

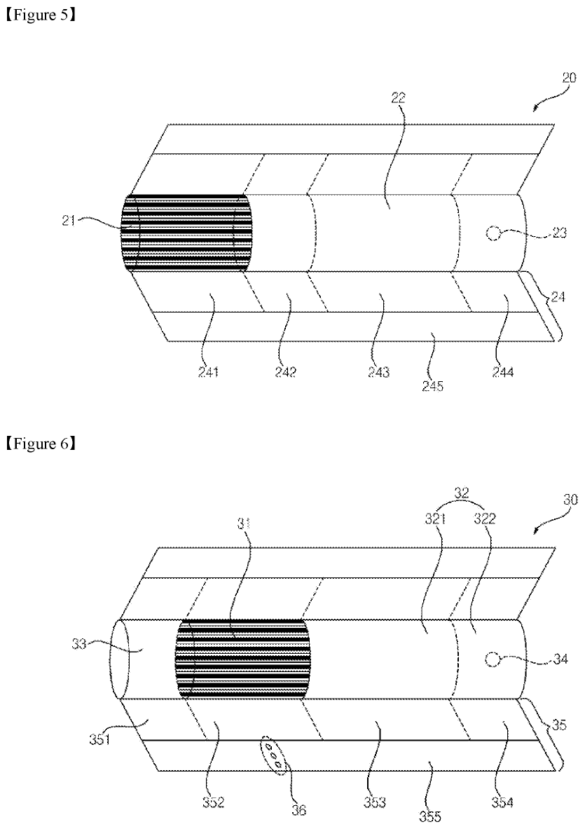

FIGS. 5 to 7 are views for explaining a stick according to embodiments of the present disclosure.

Referring to FIG. 5, the stick 20 may include a tobacco rod 21 and a filter rod 22. The first portion described above with reference to FIG. 2 may include the tobacco rod. The second portion described above with reference to FIG. 2 may include the filter rod 22.

FIG. 5 illustrates that the filter rod 22 includes a single segment. However, the filter rod 22 is not limited thereto. In other words, the filter rod 22 may include a plurality of segments. For example, the filter rod 22 may include a first segment configured to cool an aerosol and a second segment configured to filter a certain component included in the aerosol. Also, as necessary, the filter rod 22 may further include at least one segment configured to perform other functions.

A diameter of the stick 20 may be within a range of 5 mm to 9 mm, and a length of the stick 20 may be about 48 mm, but embodiments are not limited thereto. For example, a length of the tobacco rod 21 may be about 12 mm, a length of a first segment of the filter rod 22 may be about 10 mm, a length of a second segment of the filter rod 22 may be about 14 mm, and a length of a third segment of the filter rod 22 may be about 12 mm, but embodiments are not limited thereto.

The stick 20 may be wrapped using at least one wrapper 24. The wrapper 24 may have at least one hole through which external air may be introduced or internal air may be discharged. For example, the stick 20 may be wrapped using one wrapper 24. As another example, the stick 20 may be double-wrapped using at least two wrappers 24. For example, the tobacco rod 21 may be wrapped using a first wrapper 241. For example, the filter rod 22 may be wrapped using wrappers 242, 243, 244. The tobacco rod 21 and the filter rod 22 wrapped by wrappers may be combined. The stick 20 may be re-wrapped by a single wrapper 245. When each of the tobacco rod 21 and the filter rod 22 includes a plurality of segments, each segment may be wrapped using wrappers 242, 243, 244. The entirety of stick 20 composed of a plurality of segments wrapped by wrappers may be re-wrapped by another wrapper

The first wrapper 241 and the second wrapper 242 may be formed of general filter wrapping paper. For example, the first wrapper 241 and the second wrapper 242 may be porous wrapping paper or non-porous wrapping paper. Also, the first wrapper 241 and the second wrapper 242 may be made of an oil-resistant paper sheet and an aluminum laminate packaging material.

The third wrapper 243 may be made of a hard wrapping paper. For example, a basis weight of the third wrapper 243 may be within a range of 88 g/m² to 96 g/m². For example, the basis weight of the third wrapper 243 may be within a range of 90 g/m² to 94 g/m². Also, a total thickness of the third wrapper 243 may be within a range of 120 μm to 130 μm. For example, the total thickness of the third wrapper 243 may be 125 μm.

The fourth wrapper 244 may be made of an oil-resistant hard wrapping paper. For example, a basis weight of the fourth wrapper 244 may be within a range of about 88 g/m² to about 96 g/m². For example, the basis weight of the fourth wrapper 244 may be within a range of 90 g/m² to 94 g/m². Also, a total thickness of the fourth wrapper 244 may be within a range of 120 μm to 130 μm. For example, the total thickness of the fourth wrapper 244 may be 125 μm.

The fifth wrapper 245 may be made of a sterilized paper (MFW). Here, the MFW refers to a paper specially manufactured to have enhanced tensile strength, water resistance, smoothness, and the like, compared to ordinary paper. For example, a basis weight of the fifth wrapper 245 may be within a range of 57 g/m² to 63 g/m². For example, a basis weight of the fifth wrapper 245 may be about 60 g/m². Also, the total thickness of the fifth wrapper 245 may be within a range of 64 μm to 70 μm. For example, the total thickness of the fifth wrapper 245 may be 67 μm.

A predetermined material may be included in the fifth wrapper 245. Here, an example of the predetermined material may be, but is not limited to, silicon. For example, silicon exhibits characteristics like heat resistance with little change due to the temperature, oxidation resistance, resistances to various chemicals, water repellency, electrical insulation, etc. However, any material other than silicon may be applied to (or coated on) the fifth wrapper 245 without limitation as long as the material has the above-mentioned characteristics.

The fifth wrapper 245 may prevent the stick 20 from being burned. For example, when the tobacco rod 21 is heated by the heater 110, there is a possibility that the stick 20 is burned. In detail, when the temperature is raised to a temperature above the ignition point of any one of materials included in the tobacco rod 21, the stick 20 may be burned. Even in this case, since the fifth wrapper 245 include a non-combustible material, the burning of the stick 20 may be prevented.

Furthermore, the fifth wrapper 245 may prevent the aerosol generating device 100 from being contaminated by substances formed by the stick 20. Through puffs of a user, liquid substances may be formed in the stick 20. For example, as the aerosol formed by the stick 20 is cooled by the outside air, liquid materials (e.g., moisture, etc.) may be formed. As the fifth wrapper 245 wraps the stick 20, the liquid materials formed in the stick 20 may be prevented from being leaked out of the stick 20.

The tobacco rod 21 may include an aerosol generating material. For example, the aerosol generating material may include at least one of glycerin, propylene glycol, ethylene glycol, dipropylene glycol, diethylene glycol, triethylene glycol, tetraethylene glycol, and oleyl alcohol, but it is not limited thereto. Also, the tobacco rod 21 may include other additives, such as flavors, a wetting agent, and/or organic acid. Also, the tobacco rod 21 may include a flavored liquid, such as menthol or a moisturizer, which is injected to the tobacco rod 21.

The tobacco rod 21 may be manufactured in various forms. For example, the tobacco rod 21 may be formed as a sheet or a strand. Also, the tobacco rod 21 may be formed as a pipe tobacco, which is formed of tiny bits cut from a tobacco sheet. Also, the tobacco rod 21 may be surrounded by a heat conductive material. For example, the heat-conducting material may be, but is not limited to, a metal foil such as aluminum foil. For example, the heat conductive material surrounding the tobacco rod 21 may uniformly distribute heat transmitted to the tobacco rod 21, and thus, the heat conductivity applied to the tobacco rod may be increased and taste of the tobacco may be improved. Also, the heat conductive material surrounding the tobacco rod 21 may function as a susceptor heated by the induction heater. Here, although not illustrated in the drawings, the tobacco rod 21 may further include an additional susceptor, in addition to the heat conductive material surrounding the tobacco rod 21.

The filter rod 22 may include a cellulose acetate filter. Shapes of the filter rod 22 are not limited. For example, the filter rod 22 may include a cylinder-type rod or a tube-type rod having a hollow inside. Also, the filter rod 22 may include a recess-type rod. When the filter rod 22 includes a plurality of segments, at least one of the plurality of segments may have a different shape.

The first segment of the filter rod 22 may be a cellulous acetate filter. For example, the first segment may be a tube-type structure having a hollow inside. The first segment may prevent an internal material of the tobacco rod 21 from being pushed back when the heater 110 is inserted into the tobacco rod 21 and may also provide a cooling effect to aerosol. A diameter of the hollow included in the first segment may be an appropriate diameter within a range of 2 mm to 4.5 mm but is not limited thereto.

The length of the first segment may be an appropriate length within a range of 4 mm to 30 mm but is not limited thereto. For example, the length of the first segment may be 10 mm but is not limited thereto.

The second segment of the filter rod 22 cools the aerosol which is generated when the heater 110 heats the tobacco rod 21. Therefore, the user may puff the aerosol which is cooled at an appropriate temperature.

The length or diameter of the second segment may be variously determined according to the shape of the stick 20. For example, the length of the second segment may be an appropriate length within a range of 7 mm to 20 mm. Preferably, the length of the second segment may be about 14 mm but is not limited thereto.

The second segment may be manufactured by weaving a polymer fiber. In this case, a flavoring liquid may also be applied to the fiber formed of the polymer. Alternatively, the second segment may be manufactured by weaving together an additional fiber coated with a flavoring liquid and a fiber formed of a polymer. Alternatively, the second segment may be formed by a crimped polymer sheet.

For example, a polymer may be formed of a material selected from the group consisting of polyethylene (PE), polypropylene (PP), polyvinyl chloride (PVC), polyethylene terephthalate (PET), polylactic acid (PLA), cellulous acetate (CA), and aluminum coil.

As the second segment is formed by the woven polymer fiber or the crimped polymer sheet, the second segment may include a single channel or a plurality of channels extending in a longitudinal direction. Here, a channel refers to a passage through which a gas (e.g., air or aerosol) passes.

For example, the second segment formed of the crimped polymer sheet may be formed from a material having a thickness between about 5 μm and about 300 μm, for example, between about 10 μm and about 250 μm. Also, a total surface area of the second segment may be between about 300 mm2/mm and about 1000 mm2/mm. In addition, an aerosol cooling element may be formed from a material having a specific surface area between about 10 mm2/mg and about 100 mm2/mg.

The second segment may include a thread including a volatile flavor component. Here, the volatile flavor component may be menthol but is not limited thereto. For example, the thread may be filled with a sufficient amount of menthol to provide the second segment with menthol of 1.5 mg or more.

The third segment of the filter rod 22 may be a cellulous acetate filter. The length of the third segment may be an appropriate length within a range of 4 mm to 20 mm. For example, the length of the third segment may be about 12 mm but is not limited thereto.

The filter rod 22 may be manufactured to generate flavors. For example, a flavoring liquid may be injected onto the filter rod 22. For example, an additional fiber coated with a flavoring liquid may be inserted into the filter rod 22.

Also, the filter rod 22 may include at least one capsule 23. Here, the capsule 23 may generate a flavor. The capsule 23 may generate an aerosol. For example, the capsule 23 may have a configuration in which a liquid including a flavoring material is wrapped with a film. The capsule 23 may have a spherical or cylindrical shape but is not limited thereto.

Referring to FIG. 6, a stick 30 may further include a front-end plug 33. The front-end plug 33 may be located on a side of a tobacco rod 31, the side not facing a filter rod 32. The front-end plug 33 may prevent the tobacco rod 31 from being detached and prevent liquefied aerosol from flowing into the aerosol generating device 10 from the tobacco rod 31, during smoking.

The filter rod 32 may include a first segment 321 and a second segment 322. The first segment 321 may correspond to the first segment of the filter rod 22 of FIG. 4. The segment 322 may correspond to the third segment of the filter rod 22 of FIG. 4.

A diameter and a total length of the stick 30 may correspond to the diameter and a total length of the stick 20 of FIG. 4. For example, a length of the front-end plug 33 may be about 7 mm, a length of the tobacco rod 31 may be about 15 mm, a length of the first segment 321 may be about 12 mm, and a length of the second segment 322 may be about 14 mm, but embodiments are not limited thereto.

The stick 30 may be wrapped using at least one wrapper 35. The wrapper 35 may have at least one hole through which external air may be introduced or internal air may be discharged. For example, the front-end plug 33 may be wrapped using a first wrapper 351, the tobacco rod 31 may be wrapped using a second wrapper 352, the first segment 321 may be wrapped using a third wrapper 353, and the second segment 322 may be wrapped using a fourth wrapper 354. Also, the entire stick 30 may be re-wrapped using a fifth wrapper 355.

In addition, the fifth wrapper 355 may have at least one perforation 36 formed therein. For example, the perforation 36 may be formed in an area of the fifth wrapper 355 surrounding the tobacco rod 31 but is not limited thereto. For example, the perforation 36 may transfer heat formed by the heater 210 illustrated in FIG. 3 into the tobacco rod 31.

Also, the second segment 322 may include at least one capsule 34. Here, the capsule 34 may generate a flavor. The capsule 34 may generate an aerosol. For example, the capsule 34 may have a configuration in which a liquid including a flavoring material is wrapped with a film. The capsule 34 may have a spherical or cylindrical shape but is not limited thereto.

The first wrapper 351 may be formed by combining general filter wrapping paper with a metal foil such as an aluminum coil. For example, a total thickness of the first wrapper 351 may be within a range of 45 μm to 55 μm. For example, the total thickness of the first wrapper 351 may be 50.3 μm. Also, a thickness of the metal coil of the first wrapper 351 may be within a range 6 μm to 7 μm. For example, the thickness of the metal coil of the first wrapper 351 may be 6.3 μm. In addition, a basis weight of the first wrapper 351 may be within a range of 50 g/m2 to 55 g/m2. For example, the basis weight of the first wrapper 351 may be 53 g/m2.

The second wrapper 352 and the third wrapper 353 may be formed of general filter wrapping paper. For example, the second wrapper 352 and the third wrapper 353 may be porous wrapping paper or non-porous wrapping paper.

For example, porosity of the second wrapper 352 may be 35000 CU but is not limited thereto. Also, a thickness of the second wrapper 352 may be within a range of 70 μm to 80 μm. For example, the thickness of the second wrapper 352 may be 78 μm. A basis weight of the second wrapper 352 may be within a range of 20 g/m2 to 25 g/m2. For example, the basis weight of the second wrapper 352 may be 23.5 g/m2.

For example, porosity of the third wrapper 353 may be 24000 CU but is not limited thereto. Also, a thickness of the third wrapper 353 may be in a range of about 60 μm to about 70 μm. For example, the thickness of the third wrapper 353 may be 68 μm. A basis weight of the third wrapper 353 may be in a range of about 20 g/m2 to about 25 g/m2. For example, the basis weight of the third wrapper 353 may be 21 g/m2.

The fourth wrapper 354 may be formed of PLA laminated paper. Here, the PLA laminated paper refers to three-layer paper including a paper layer, a PLA layer, and a paper layer. For example, a thickness of the fourth wrapper 353 may be in a range of 100 μm to 120 μm. For example, the thickness of the fourth wrapper 353 may be 110 μm. Also, a basis weight of the fourth wrapper 354 may be in a range of 80 g/m2 to 100 g/m2. For example, the basis weight of the fourth wrapper 354 may be 88 g/m2.

The fifth wrapper 355 may be formed of sterilized paper (MFW). Here, the sterilized paper (MFW) refers to paper which is particularly manufactured to improve tensile strength, water resistance, smoothness, and the like more than ordinary paper. For example, a basis weight of the fifth wrapper 355 may be in a range of 57 g/m2 to 63 g/m2. For example, the basis weight of the fifth wrapper 355 may be 60 g/m2. Also, a thickness of the fifth wrapper 355 may be in a range of 64 μm to 70 μm. For example, the thickness of the fifth wrapper 355 may be 67 μm.

The fifth wrapper 355 may include a preset material added thereto. An example of the material may include silicon, but it is not limited thereto. Silicon has characteristics such as heat resistance robust to temperature conditions, oxidation resistance, resistance to various chemicals, water repellency to water, and electrical insulation, etc. Besides silicon, any other materials having characteristics as described above may be applied to (or coated on) the fifth wrapper 355 without limitation.

The front-end plug 33 may be formed of cellulous acetate. For example, the front-end plug 33 may be formed by adding a plasticizer (e.g., triacetin) to cellulous acetate tow. Mono-denier of filaments constituting the cellulous acetate tow may be in a range of 1.0 to 10.0. For example, the mono-denier of filaments constituting the cellulous acetate tow may be within a range of 4.0 to 6.0. For example, the mono-denier of the filaments of the front-end plug 33 may be 5.0. Also, a cross-section of the filaments constituting the front-end plug 33 may be a Y shape. Total denier of the front-end plug 33 may be in a range of 20000 to 30000. For example, the total denier of the front-end plug 33 may be within a range of 25000 to 30000. For example, the total denier of the front-end plug 33 may be 28000.

Also, as needed, the front-end plug 33 may include at least one channel. A cross-sectional shape of the channel may be manufactured in various shapes.

The tobacco rod 31 may correspond to the tobacco rod 21 described above with reference to FIG. 4. Therefore, hereinafter, the detailed description of the tobacco rod 31 will be omitted.

The first segment 321 may be formed of cellulous acetate. For example, the first segment 321 may be a tube-type structure having a hollow inside. The first segment 321 may be manufactured by adding a plasticizer (e.g., triacetin) to cellulous acetate tow. For example, mono-denier and total denier of the first segment 321 may be the same as the mono-denier and total denier of the front-end plug 33.

The second segment 322 may be formed of cellulous acetate. Mono denier of filaments constituting the second segment 322 may be in a range of 1.0 to 10.0. For example, the mono denier of the filaments of the second segment 322 may be within a range of about 8.0 to about 10.0. For example, the mono denier of the filaments of the second segment 322 may be 9.0. Also, a cross-section of the filaments of the second segment 322 may be a Y shape. Total denier of the second segment 322 may be in a range of 20000 to 30000. For example, the total denier of the second segment 322 may be 25000.

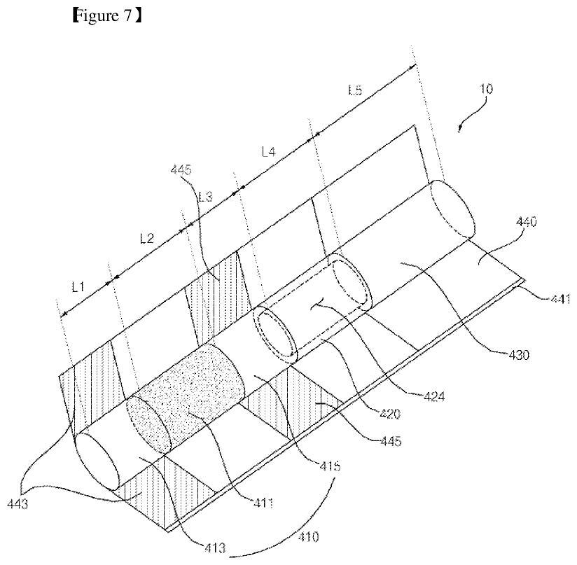

Referring to FIG. 7, the aforementioned stick 40 may include a medium portion 410. The stick 40 may include a cooling portion 420. The stick 40 may include a filter portion 430. The cooling portion 420 may be disposed between the medium portion 410 and the filter portion 430. The stick 40 may include a wrapper 440. The wrapper 440 may wrap the medium portion 410. The wrapper 440 may wrap the cooling portion 420. The wrapper 440 may wrap the filter portion 430. The stick 40 may have a cylindrical shape.

The medium portion 410 may include a medium 411. The medium portion 410 may include a first medium cover 413. The medium portion 410 may include a second medium cover 415. The medium 411 may be disposed between the first medium cover 413 and the second medium cover 415. The first medium cover 413 may be disposed at one end of the stick 40. The medium portion 410 may have a length of 24 mm.

The medium 411 may contain a multicomponent substance. The substance contained in the medium may be a multicomponent flavoring substance. The medium 411 may be composed of a plurality of granules. Each of the plurality of granules may have a size of 0.4 mm to 1.12 mm. The granules may account for approximately 70% of the volume of the medium 411. The length L2 of the medium 411 may be 10 mm. The first medium cover 413 may be made of an acetate material. The second medium cover 415 may be made of an acetate material. The first medium cover 413 may be made of a paper material. The second medium cover 415 may be made of a paper material. At least one of the first medium cover 413 or the second medium cover 415 may be made of a paper material, and may be crumpled so as to be wrinkled, and a plurality of gaps may be formed between the wrinkles so that air flows therethrough. Each of the gaps may be smaller than each of the granules of the medium 411. The length L1 of the first medium cover 413 may be shorter than the length L2 of the medium 411. The length L3 of the second medium cover 415 may be shorter than the length L2 of the medium 411. The length L1 of the first medium cover 413 may be 7 mm. The length L2 of the second medium cover 415 may be 7 mm.

Accordingly, each of the granules of the medium 411 may be prevented from being separated from the medium portion 410 and the stick 40.

The cooling portion 420 may have a cylindrical shape. The cooling portion 420 may have a hollow shape. The cooling portion 420 may be disposed between the medium portion 410 and the filter portion 430. The cooling portion 420 may be disposed between the second medium cover 415 and the filter portion 430. The cooling portion 420 may be formed in the shape of a tube that surrounds a cooling path 424 formed therein. The cooling portion 420 may be thicker than the wrapper 440. The cooling portion 420 may be made of a paper material thicker than that of the wrapper 440. The length L4 of the cooling portion 420 may be equal or similar to the length L2 of the medium 411. The length L4 of each of the cooling portion 420 and the cooling path 424 may be 10 mm. When the stick 40 is inserted into the aerosol-generating device, at least part of the cooling portion 420 may be exposed to the outside of the aerosol-generating device.

Accordingly, the cooling portion 420 may support the medium portion 410 and the filter portion 430 and may secure the rigidity of the stick 40. In addition, the cooling portion 420 may support the wrapper 440 between the medium portion 410 and the filter portion 430 and may provide a portion to which the wrapper 440 is adhered. In addition, the heated air and aerosol may be cooled while passing through the cooling path 424 in the cooling portion 420.

The filter portion 430 may be composed of a filter made of an acetate material. The filter portion 430 may be disposed at the other end of the stick 40. When the stick 40 is inserted into the aerosol-generating device, the filter portion 430 may be exposed to the outside of the aerosol-generating device. The user may inhale air in the state of holding the filter portion 430 in the mouth. The length L5 of the filter portion 430 may be 14 mm.

The wrapper 440 may wrap or surround the medium portion 410, the cooling portion 420, and the filter portion 430. The wrapper 440 may form the external appearance of the stick 40. The wrapper 440 may be made of a paper material. An adhesive portion 441 may be formed along one edge of the wrapper 440. The wrapper 440 may surround the medium portion 410, the cooling portion 420, and the filter portion 430, and the adhesive portion 441 formed along one edge of the wrapper 440 and the other edge thereof may be adhered to each other. The wrapper 440 may surround the medium portion 410, the cooling portion 420, and the filter portion 430, but may not cover one end or the other end of the stick 40.

Accordingly, the wrapper 440 may fix the medium portion 410, the cooling portion 420, and the filter portion 430, and may prevent these components from being separated from the stick 40.

A first thin film 443 may be disposed at a position corresponding to the first medium cover 413. The first thin film 443 may be disposed between the wrapper 440 and the first medium cover 413, or may be disposed outside the wrapper 440. The first thin film 443 may surround the first medium cover 413. The first thin film 443 may be made of a metal material. The first thin film 443 may be made of an aluminum material. The first thin film 443 may be in close contact with the wrapper 440 or may be coated thereon.

A second thin film 445 may be disposed at a position corresponding to the second medium cover 415. The second thin film 445 may be disposed between the wrapper 440 and the second medium cover 415 or may be disposed outside the wrapper 440. The second thin film 445 may be made of a metal material. The second thin film 445 may be made of an aluminum material. The second thin film 445 may be in close contact with the wrapper 440 or may be coated thereon.

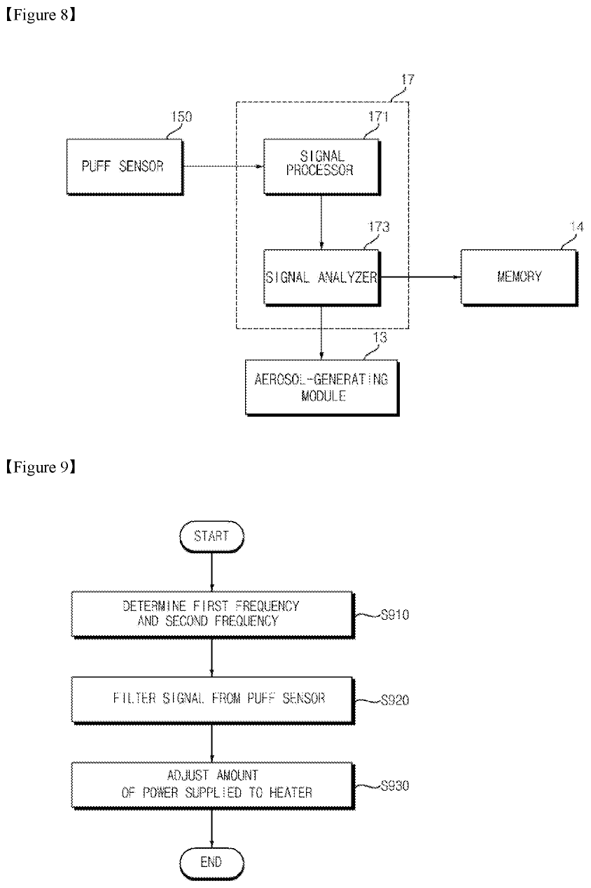

FIG. 8 is a diagram for explaining the configuration of an aerosol-generating device according to an embodiment of the present disclosure.

Referring to FIG. 8, the aerosol-generating device 10 may include an aerosol-generating module 13, a memory 14, a controller 17, and/or a puff sensor 150.

The puff sensor 150 may output a signal corresponding to a puff. For example, the puff sensor 150 may output a signal corresponding to the internal pressure of the aerosol-generating device 10. Here, the internal pressure of the aerosol-generating device 10 may correspond to the pressure in a flow path through which gas flows. In this embodiment, the puff sensor 150 is described as being implemented as a pressure sensor configured to output a signal corresponding to the internal pressure of the aerosol-generating device 10, but the present disclosure is not limited thereto.

The controller 17 may include a signal processor 171 and/or a signal analyzer 173.

The signal processor 171 may process a signal from the puff sensor 150. The signal processor 171 may filter a signal from the puff sensor 150 through a filter using at least one cutoff frequency. For example, the signal processor 171 may pass a signal in a predetermined frequency band corresponding to the cutoff frequency. For example, the signal processor 171 may remove a signal in a predetermined frequency band corresponding to the cutoff frequency.

The signal processor 171 may include a digital filter. The digital filter may be implemented as an algorithm for processing a digital signal based on at least one cutoff frequency. In the present disclosure, the filter provided in the signal processor 171 in order to filter a signal may be a digital filter.

The signal processor 171 may change the cutoff frequency. For example, the signal processor 171 may change the cutoff frequency in order to adjust the frequency band through which the signal passes.

The signal processor 171 may further include an analog-to-digital converter (ADC), which converts an analog signal into a digital signal. The analog-to-digital converter (ADC) may convert an analog signal output from the puff sensor 150 into a digital signal. In this case, the signal processor 171 may process the digital signal, into which the signal from the puff sensor 150 has been converted, using the digital filter.

Alternatively, the analog-to-digital converter (ADC) may be provided separately from the signal processor 171. For example, the analog-to-digital converter (ADC) may be electrically connected to an output terminal of the puff sensor 150 and to an input terminal of the signal processor 171.

The signal processor 171 may process a signal from the puff sensor 150 using each of a plurality of digital filters. For example, the signal processor 171 may process signals from the puff sensor 150 using a plurality of digital filters, which respectively correspond to a plurality of low-pass filters having different cutoff frequencies.

The signal analyzer 173 may determine a puff based on the signal processed by the signal processor 171. For example, the signal analyzer 173 may determine whether a puff occurs based on the sensing value of the signal from the puff sensor 150, processed by the signal processor 171. For example, the signal analyzer 173 may determine the intensity of a puff based on the sensing value of the signal from the puff sensor 150, processed by the signal processor 171. For example, the signal analyzer 173 may determine the time period during which a puff occurs (hereinafter referred to as a puff time period) based on the sensing value of the signal from the puff sensor 150, processed by the signal processor 171.

Upon determining that a puff has occurred, the signal analyzer 173 may control the aerosol-generating module 13. For example, upon determining that a puff has occurred, the signal analyzer 173 may control the aerosol-generating module 13 such that power is supplied to a heater included in the aerosol-generating module 13.

Upon determining that a puff has occurred, the signal analyzer 173 may update data stored in the memory 14. For example, upon determining that a puff has occurred, the signal analyzer 173 may update the current number of puffs stored in the memory 14. For example, upon determining that a puff has occurred, the signal analyzer 173 may update data on the puff time period stored in the memory 14.

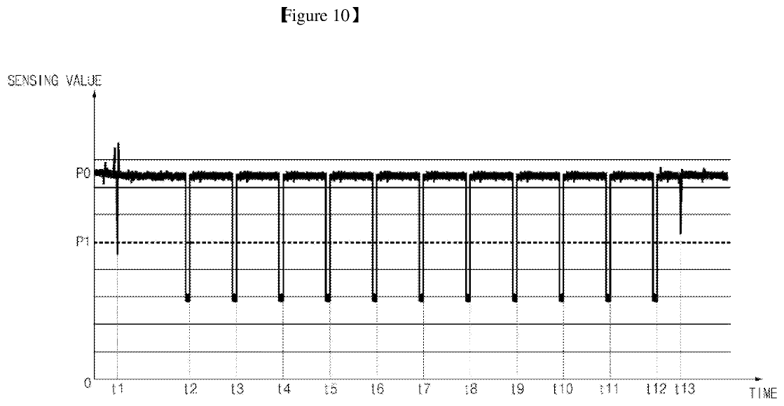

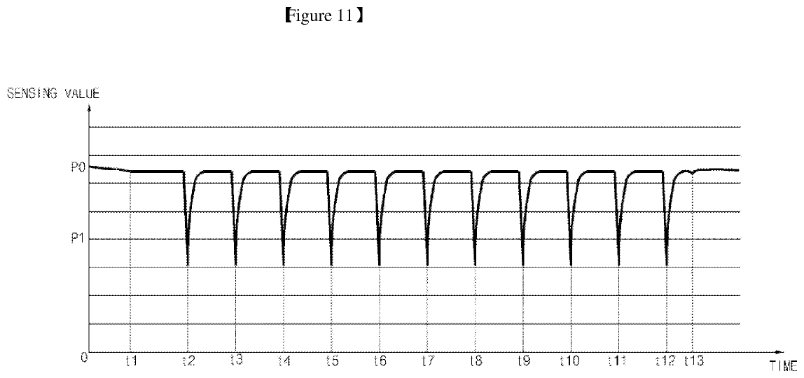

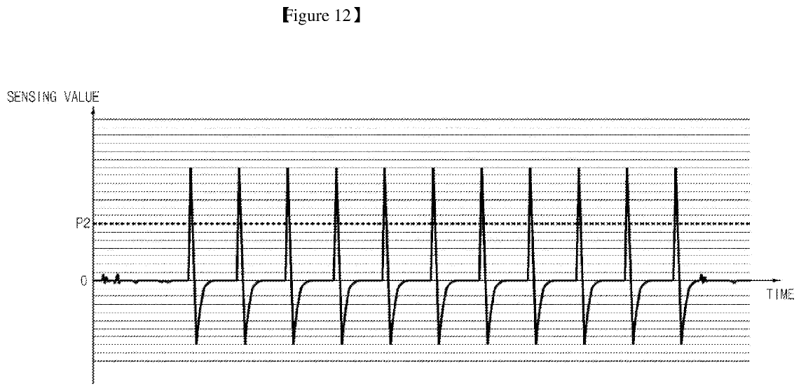

FIG. 9 is a flowchart showing an operation method of an aerosol-generating device according to an embodiment of the present disclosure.

Referring to FIG. 9, the aerosol-generating device 10 may determine a first frequency corresponding to a first puff time period and a second frequency corresponding to a second puff time period in operation S910. For example, the aerosol-generating device 10 may determine the first frequency and the second frequency when powered on.

Here, the first puff time period may be a relatively short time period of inhalation of an aerosol by the user, and the second puff time period may be a relatively long time period of inhalation of an aerosol by the user. In this case, since the first puff time period is shorter than the second puff time period, the first frequency may be set to be lower than the second frequency. For example, when the first puff time period is 0.5 seconds and the second puff time period is 3 seconds, the first frequency corresponding to the first puff time period may be set to 0.9 Hz, and the second frequency corresponding to the second puff time period may be set to 2.0 Hz.

According to an embodiment, the aerosol-generating device 10 may determine the first puff time period and the second puff time period based on the data on the puff time periods stored in the memory 14. For example, the aerosol-generating device 10 may respectively determine the minimum value and the maximum value of the puff time periods stored in the memory 14 to be the first puff time period and the second puff time period. For example, the aerosol-generating device 10 may extract a predetermined number of puff time periods in ascending order from the shortest puff time period, from among the puff time periods stored in the memory 14. In this case, the aerosol-generating device 10 may determine the representative value of the extracted predetermined number of puff time periods to be the first puff time period.

The aerosol-generating device 10 may determine the first frequency and the second frequency based on the correspondence between the puff time periods and the frequencies. For example, the aerosol-generating device 10 may determine the first frequency corresponding to the first puff time period and the second frequency corresponding to the second puff time period with reference to a lookup table containing information on correspondence between the puff time periods stored in the memory 14 and the frequencies.

The aerosol-generating device 10 may filter a signal from the puff sensor 150 based on the first frequency and the second frequency in operation S920. For example, the aerosol-generating device 10 may filter a signal from the puff sensor 150 using at least one digital filter. In this case, the digital filter may be implemented as a low-pass filter, a high-pass filter, a band-pass filter, or combinations thereof. In the present disclosure, the digital filter is described by way of example as being implemented as a low-pass filter, but the present disclosure is not limited thereto.

The cutoff frequency of the digital filter may be within a frequency band corresponding to the range from the first frequency to the second frequency. That is, the minimum value of the cutoff frequency may correspond to the first frequency, and the maximum value of the cutoff frequency may correspond to the second frequency.

For example, in the case in which a signal from the puff sensor 150 is filtered by one low-pass filter, the cutoff frequency of the low-pass filter may be set to 1.0 Hz, falling within a frequency band corresponding to the range from the first frequency to the second frequency, i.e. from 0.9 Hz to 2.0 Hz. For example, in the case in which signals from the puff sensor 150 are filtered by a plurality of low-pass filters having different cutoff frequencies, the cutoff frequency of the first low-pass filter may be set to 0.9 Hz, which is the first frequency, and the cutoff frequency of the second low-pass filter may be set to 2.0 Hz, which is the second frequency.

The aerosol-generating device 10 may adjust the power that is supplied to the heater included in the aerosol-generating module 13 based on the result of filtering the signal from the puff sensor 150 in operation S930.

The aerosol-generating device 10 may determine whether a puff occurs based on the sensing value of the filtered signal from the puff sensor 150. Upon determining that a puff has occurred, the aerosol-generating device 10 may control the aerosol-generating module 13 such that power is supplied to the heater included in the aerosol-generating module 13. In this case, the aerosol-generating device 10 may adjust the power that is supplied to the heater based on the temperature profile, the current number of puffs, and the puff time period stored in the memory 14.

Referring to FIG. 10, a signal output from the puff sensor 150 may include a noise component. For example, when the user shakes the aerosol-generating device 10, when vibration occurs in the space in which the aerosol-generating device 10 is located, such as a vehicle, or when the stick 20 is inserted into the aerosol-generating device 10, a noise component may be included in the signal output from the puff sensor 150 due to a change in the internal pressure of the aerosol-generating device 10.

The sensing value of the signal output from the puff sensor 150 may be reduced from P0, which is a reference value, to a value less than P1 due to inhalation by the user at each of point in times t2 to t12. Here, the reference value P0 may be a predetermined sensing value corresponding to the case in which no puff occurs. In this case, the aerosol-generating device 10 may determine that a puff has occurred based on the reduction in the sensing value of the signal output from the puff sensor 150 to a value less than P1. In addition, upon determining that a puff has occurred, the aerosol-generating device 10 may heat the heater in order to generate an aerosol.

Meanwhile, at each of point in times t1 and t13, the sensing value of the signal output from the puff sensor 150 may be changed from P0 by a noise component included in the signal output from the puff sensor 150. In this case, since the sensing value of the signal output from the puff sensor 150 exceeds P0 at the point in time t13, the heater included in the aerosol-generating module 13 may not be heated. Meanwhile, since the sensing value of the signal output from the puff sensor 150 decreases below P0 at the point in time t1, the heater included in the aerosol-generating module 13 may be heated in order to generate an aerosol.

Referring to FIG. 11, when the signal output from the puff sensor 150 is filtered, a noise component included in the signal output from the puff sensor 150 may be removed.

In particular, since the sensing value of the filtered signal corresponds to the reference value P0 at the point in time t1, the heater included in the aerosol-generating module 13 may not be heated at the point in time t1.

Meanwhile, according to an embodiment of the present disclosure, the aerosol-generating device 10 may filter the signal output from the puff sensor 150 using each of a plurality of filters having different cutoff frequencies. In this case, the aerosol-generating device 10 may determine whether a puff occurs based on the difference between the results of filtering using the plurality of filters.

For example, the aerosol-generating device 10 may filter the signal output from the puff sensor 150 using each of the first low-pass filter, which has a cutoff frequency set to 0.9 Hz, which is the first frequency, and the second low-pass filter, which has a cutoff frequency set to 2.0 Hz, which is the second frequency. In this case, the aerosol-generating device 10 may determine whether a puff occurs based on the difference between the sensing value of the signal filtered by the first low-pass filter and the sensing value of the signal filtered by the second low-pass filter.

Referring to FIG. 12, in the case in which the difference between the results of filtering using the plurality of filters is used, the reference value, which is a criterion for determining a puff, may be zero. That is, in the case in which there is no change in the internal pressure of the aerosol-generating device 10 due to a puff, the sensing value of the signal output from the puff sensor 150 may be maintained within a predetermined range. In this case, all of the sensing values of the signals filtered by the plurality of filters may be within a predetermined range, and thus the difference between the sensing values of the signals filtered by the plurality of filters may be zero.

Meanwhile, because the cutoff frequencies of the plurality of filters are different from each other, the difference between the sensing values of the signals filtered by the plurality of filters may increase during the period in which a puff occurs. In this case, the aerosol-generating device 10 may determine that a puff has occurred based on the increase in the difference between the sensing values of the signals filtered by the plurality of filters to P2 or greater.

As described above, in the case in which the aerosol-generating device 10 determines whether a puff occurs based on the difference between the results of filtering using the plurality of filters, the reference value, which is a criterion for determining a puff, may be zero, and may not be influenced by changes in ambient pressure around the aerosol-generating device 10. Consequently, it is possible to minimize the influence of factors that deteriorate the accuracy of a determination as to whether a puff occurs.

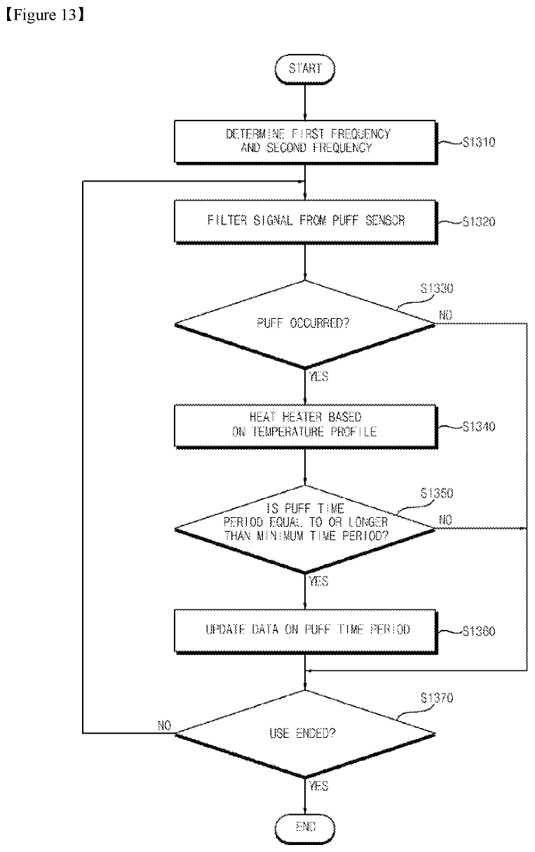

FIG. 13 is a flowchart showing an operation method of an aerosol-generating device according to another embodiment of the present disclosure. A detailed description of the same content as that described with reference to FIGS. 8 and 9 will be omitted.

Referring to FIG. 13, the aerosol-generating device 10 may determine a first frequency corresponding to the first puff time period and a second frequency corresponding to the second puff time period in operation S1310.

The aerosol-generating device 10 may filter the signal from the puff sensor 150 based on the first frequency and the second frequency in operation S1320.

The aerosol-generating device 10 may determine whether a puff occurs in operation S1330.

Upon determining that a puff has occurred, the aerosol-generating device 10 may heat the heater based on the temperature profile stored in the memory 14 in operation S1340. In this case, the aerosol-generating device 10 may adjust the power that is supplied to the heater based on the temperature profile, the current number of puffs, and the puff time period. For example, while puffs are continuously performed, the aerosol-generating device 10 may supply power corresponding to the current number of puffs to the heater based on the temperature profile.

The aerosol-generating device 10 may determine whether the puff time period is equal to or longer than a predetermined minimum time period in operation S1350. Here, the puff time period may be a time period from the point in time of occurrence of the puff to the point in time of end of the puff.

When the puff time period is equal to or longer than the minimum time period, the aerosol-generating device 10 may update data on the puff time period stored in the memory 14 in operation S1360. For example, when the puff time period is 2 seconds, which is longer than 0.3 seconds, which is the minimum time period, the aerosol-generating device 10 may add 2 seconds to the data on the puff time period stored in the memory 14.

Meanwhile, when the puff time period is shorter than the minimum time period, the aerosol-generating device 10 may skip updating the data on the puff time period stored in the memory 14. For example, when the puff time period is 0.2 seconds, which is shorter than 0.3 seconds, which is the minimum time period, the aerosol-generating device 10 may determine that the corresponding puff is an abnormal puff.

The aerosol-generating device 10 may determine whether use thereof for generating an aerosol ends in operation S1370. For example, when powered off, the aerosol-generating device 10 may determine that use thereof for generating an aerosol ends. For example, when the stick 20 is removed therefrom, the aerosol-generating device 10 may determine that use thereof for generating an aerosol ends.

As described above, according to at least one of the embodiments of the present disclosure, a signal from the puff sensor 150 may be accurately filtered based on digital filtering using a plurality of frequencies.

According to at least one of the embodiments of the present disclosure, the accuracy of filtering of a signal from the puff sensor 150 may be improved based on a user's puff time period.

Referring to FIGS. 1 to 13, an aerosol-generating device 10 in accordance with one aspect of the present disclosure may include a heater configured to heat an aerosol-generating substance, a puff sensor 150 configured to detect a puff, and a controller 17 configured to process a signal from the puff sensor 150. The controller 17 may determine a first frequency corresponding to a first puff time period and a second frequency corresponding to a second puff time period, which is longer than the first puff time period, may filter the signal from the puff sensor 150 based on the first frequency and the second frequency, and may adjust the power supplied to the heater based on the result of filtering. The first frequency may be a frequency lower than the second frequency.

In addition, in accordance with another aspect of the present disclosure, the controller 17 may filter the signal from the puff sensor 150 using at least one digital filter, and the digital filter may have a cutoff frequency within a frequency band corresponding to the range from the first frequency to the second frequency.

In addition, in accordance with another aspect of the present disclosure, the controller 17 may filter the signal from the puff sensor 150 using each of a plurality of digital filters having different cutoff frequencies, and may determine whether a puff occurs based on the difference between results of filtering using the plurality of digital filters. Each of the plurality of digital filters may have a cutoff frequency within a frequency band corresponding to the range from the first frequency to the second frequency.

In addition, in accordance with another aspect of the present disclosure, one of the plurality of digital filters may have a cutoff frequency equivalent to the first frequency, and the remaining one of the plurality of digital filters may have a cutoff frequency equivalent to the second frequency.

In addition, in accordance with another aspect of the present disclosure, the aerosol-generating device may further include a memory 14 configured to store data on a puff time period. The controller 17 may update the data on the puff time period based on the time period during which a puff is detected by the puff sensor 150, and may determine the first puff time period and the second puff time period based on the data on the puff time period stored in the memory 14.

In addition, in accordance with another aspect of the present disclosure, when the time period during which a puff is detected is shorter than a predetermined minimum time period, the controller 17 may skip updating the data on the puff time period.

In addition, in accordance with another aspect of the present disclosure, the aerosol-generating device may further include a memory 14 configured to store the data on the puff time period. The controller 17 may determine the minimum value of the puff time periods stored in the memory 14 to be the first puff time period, and may determine the maximum value of the puff time periods stored in the memory 14 to be the second puff time period.

An operation method of an aerosol-generating device 10 in accordance with one aspect of the present disclosure may include determining a first frequency corresponding to a first puff time period and a second frequency corresponding to a second puff time period, which is longer than the first puff time period, filtering a signal from a puff sensor 150, configured to detect a puff, based on the first frequency and the second frequency, and adjusting the power supplied to a heater, configured to heat an aerosol-generating substance, based on the result of the filtering. The first frequency may be a frequency lower than the second frequency.

In addition, in accordance with another aspect of the present disclosure, the filtering may include filtering the signal from the puff sensor 150 using at least one digital filter, and the digital filter may have a cutoff frequency within a frequency band corresponding to the range from the first frequency to the second frequency.

In addition, in accordance with another aspect of the present disclosure, the filtering may include filtering the signal from the puff sensor 150 using each of a plurality of digital filters having different cutoff frequencies and determining whether a puff occurs based on the difference between results of the filtering using the plurality of digital filters. Each of the plurality of digital filters may have a cutoff frequency within a frequency band corresponding to the range from the first frequency to the second frequency.

In addition, in accordance with another aspect of the present disclosure, the method may further include updating data on the puff time period stored in a memory 14 based on the time period during which a puff is detected by the puff sensor 150. The determining a first frequency and a second frequency may include determining the first puff time period and the second puff time period based on the data on the puff time period stored in the memory 14.

In addition, in accordance with another aspect of the present disclosure, the method may further include skipping updating the data on the puff time period when the time period during which a puff is detected is shorter than a predetermined minimum time period.

In addition, in accordance with another aspect of the present disclosure, the determining the first puff time period and the second puff time period may include determining the minimum value of the puff time periods stored in the memory 14 to be the first puff time period and determining the maximum value of the puff time periods stored in the memory 14 to be the second puff time period.

Certain embodiments or other embodiments of the disclosure described above are not mutually exclusive or distinct from each other. Any or all elements of the embodiments of the disclosure described above may be combined with another or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An aerosol-generating device comprising:
a heater configured to heat an aerosol-generating substance;
a puff sensor configured to detect a puff; and
a controller configured to:
receive a signal from the puff sensor,
determine a first frequency corresponding to a first puff time period and a second frequency corresponding to a second puff time period, wherein the second puff time period is longer than the first puff time period;
filter the signal from the puff sensor based on the first frequency and the second frequency; and
adjust power supplied to the heater based on a result of the filtering the signal,
wherein the first frequency is a frequency lower than the second frequency.

2. The aerosol-generating device according to claim 1, wherein the controller is further configured to perform the filtering the signal from the puff sensor using at least one digital filter,
wherein the digital filter includes a cutoff frequency within a frequency band corresponding to a range from the first frequency to the second frequency.

3. The aerosol-generating device according to claim 1, wherein the controller is further configured to:
perform the filtering the signal from the puff sensor using each of a plurality of digital filters having respectively different cutoff frequencies, and
determine whether the puff occurs based on a difference between results of filtering using the plurality of digital filters, and
wherein each of the plurality of digital filters includes a cutoff frequency within a frequency band corresponding to a range from the first frequency to the second frequency.

4. The aerosol-generating device according to claim 3, wherein one of the plurality of digital filters includes a cutoff frequency equivalent to the first frequency, and a remaining one of the plurality of digital filters includes a cutoff frequency equivalent to the second frequency.

5. The aerosol-generating device according to claim 1, further comprising:
a memory configured to store data relating to puff time periods,
wherein the controller is further configured to:
update the data of the puff time periods based on a time period during which the puff is detected by the puff sensor, and
determine the first puff time period and the second puff time period based on the data of the puff time periods stored in the memory.

6. The aerosol-generating device according to claim 5, wherein the controller is further configured to skip updating the data of the puff time periods in response to the time period during which the puff is detected being shorter than a predetermined minimum time period.

7. The aerosol-generating device according to claim 1, further comprising:
a memory configured to store data relating to puff time periods,
wherein the controller is further configured to:
determine a minimum value of the puff time periods stored in the memory to be the first puff time period, and
determine a maximum value of the puff time periods stored in the memory to be the second puff time period.

8. The aerosol-generating device according to claim 1, wherein the first puff time period and the second puff time period respectively correspond to periods of time during which first and second puffs are detected by the puff sensor.

9. A method for operating an aerosol-generating device, the method comprising:
determining a first frequency corresponding to a first puff time period and a second frequency corresponding to a second puff time period, wherein the second puff time period is longer than the first puff time period;
filtering a signal from a puff sensor based on the first frequency and the second frequency; and
adjusting power supplied to a heater based on a result of the filtering the signal,
wherein the first frequency is a frequency lower than the second frequency.

10. The method according to claim 9, wherein the filtering comprises filtering the signal from the puff sensor using at least one digital filter,
wherein the digital filter includes a cutoff frequency within a frequency band corresponding to a range from the first frequency to the second frequency.

11. The method according to claim 9, wherein the filtering comprises:
filtering the signal from the puff sensor using each of a plurality of digital filters having respectively different cutoff frequencies; and
determining whether a puff occurs based on a difference between results of the filtering using the plurality of digital filters, and
wherein each of the plurality of digital filters includes a cutoff frequency within a frequency band corresponding to a range from the first frequency to the second frequency.

12. The method according to claim 11, wherein one of the plurality of digital filters includes a cutoff frequency equivalent to the first frequency, and a remaining one of the plurality of digital filters includes a cutoff frequency equivalent to the second frequency.

13. The method according to claim 9, further comprising:
updating data relating to puff time periods stored in a memory based on a time period during which a puff is detected by the puff sensor,
wherein the determining the first frequency and the second frequency comprises determining the first puff time period and the second puff time period based on the data of the puff time periods stored in the memory.

14. The method according to claim 13, further comprising:
skipping updating the data of the puff time periods in response to the time period during which the puff being detected is shorter than a predetermined minimum time period.

15. The method according to claim 9, further comprising:
determining a minimum value of the puff time periods stored in a memory to be the first puff time period; and
determining a maximum value of the puff time periods stored in the memory to be the second puff time period.
